(19) United States
(12) Patent Application Publication
(10) Pub. No.: US 2007/0081569 A1
(43) Pub. Date: Apr. 12, 2007

(54) Photonic quantum ring laser for low power consumption display device

(75) Inventors: O'Dae Kwon, Kyungsangbuk-do (KR); Joongwoo Bae, Chungcheongnam-do (KR); Sung-Jae An, Busan (KR); Dongkwon Kim, Seoul (KR)

Correspondence Address: BACON & THOMAS, PLLC, 625 SLATERS LANE, FOURTH FLOOR, ALEXANDRIA, VA, 22314, US

(73) Assignee: POSTECH FOUNDATION, Kyungsangbuk-do (KR)

(21) Appl. No.: 10/578,619

(22) PCT Filed: Mar. 23, 2005
(86) PCT No.: PCT/KR05/00847

§ 371 Date: May 8, 2006

(30) Foreign Application Priority Data
Mar. 25, 2004 (KR) 10 2004 0020485

(51) Int. Cl. H01S 5/00

(52) U.S. Cl. 372/43.01

(57) ABSTRACT

A three-dimensional (3D) photonic quantum ring (PQR) laser for a low power consumption display, wherein the PQR laser has a sufficient small radius to adjust an inter-mode spacing (IMS) of oscillation modes discretely multi-wavelength-oscillating in an envelope wavelength range within the gain profile of a given semiconductor material of the PQR laser so that the IMS has a maximal value and the number of the oscillation modes is minimized. The PQR laser exhibits multi-wavelength oscillation characteristics according to a 3D toroidal cavity structure, and is designed to exhibit a threshold current lower than those of LEDs and to have multi-wavelength modes in an envelope wavelength range of several nm to several tens of nm. The PQR laser consumes reduced power while maintaining desired color and high brightness equal to those of the LEDs, through an adjustment of the multi-wavelength oscillation characteristics and IMS of the PQR laser.

### TECHNICAL FIELD

The present invention relates to a semiconductor laser, and, more particularly, to a photonic quantum ring (PQR) laser having multi-wavelength oscillation characteristics suitable for a low power consumption display.

### BACKGROUND ART

Light emitting diodes (LEDs), which are most highlighted in display fields, basically have excellent characteristics such as superior anti-vibration, high reliability, and low power consumption. Such LEDs have been advanced so that they have improved characteristics such as variations in brightness and emission wavelength within a wide range and possibility of mass production. As a result, application of such LEDs has been extended over the whole field of industry, for example, backlight sources of mobile displays, signposts on highways, stock quotation boards, subway guide boards, light emitters installed in vehicles, and the like. In particular, such LEDs have been applied even to traffic signal lamps, for the purpose of reducing the consumption of energy. Although LEDs can emit light of the three primary colors by virtue of an emission wavelength range thereof extended in accordance with gain materials used for the LEDs, such as GaInN, GaAsP and InGaAsP, they have a drawback in that the full-width half maximum (FWHM) thereof varying depending on wavelength generally has a wide wavelength distribution of several tens of nm to 100 nm, as shown in an intensity distribution graph of LEDs.

Research has been made to provide a resonant cavity LED (RCLED) configured by adding a resonator having a low reflectivity to an LED having a basic structure to achieve improvements in straightness and intensity of light and temperature stability or to achieve a reduction in FWHM to several nm, and thus, to achieve a reduction in power consumption while maintaining brightness.

### DISCLOSURE OF INVENTION

### Technical Problem

However, the RCLED has a drawback in that it has an extremely high FWHM due to the resonator having a low quality factor (Q), as compared to lasers.

Accordingly, it is required to provide a new low power consumption display device which exhibits low power consumption while maintaining desired color and high brightness equal to those of LEDs.

### Technical Solution

It is, therefore, an object of the invention to provide a PQR laser suitable for a low power consumption display device, which exhibits low threshold current, as compared to LEDs, while maintaining desired color and brightness equal to those of LEDs.

In accordance with a preferred embodiment of the present invention, there is provided a three-dimensional (3D) photonic quantum ring (PQR) laser for a low power consumption display, wherein the PQR laser has a sufficient small radius to adjust an inter-mode spacing (IMS) of oscillation modes discretely multi-wavelength-oscillating in an envelope wavelength range within the gain profile of a given semiconductor material of the PQR laser so that the IMS has a maximal value.

In accordance with another preferred embodiment of the present invention, there is provided a three-dimensional (3D) photonic quantum ring (PQR) laser for a low power consumption display, wherein the PQR laser has a sufficient small radius to adjust that the number of oscillation modes discretely multi-wavelength-oscillating in an envelope wavelength range within the gain profile of a given semiconductor material of the PQR laser has a value of 1.

### ADVANTAGEOUS EFFECTS

Accordingly, the display device of the present invention can be substituted for conventional LEDs having an emission wavelength FWHM of several tens of nm to 100 nm to be used for display devices.

### BRIEF DESCRIPTION OF THE DRAWINGS

The above and other objects and features of the present invention will become apparent from the following description of preferred embodiments given in conjunction with accompanying drawings, in which:

FIGS. 1 and 2 are cross-sectional and partially-enlarged views illustrating a three dimensional whispering gallery (WG) photonic quantum ring (PQR) laser using a circular vertical-cavity surface-emitting laser (VCSEL) like structure, respectively;

FIGS. 3, 4 and 5 are a schematic view illustrating a 3D toroidal cavity structure of a PQR laser, and photographs of CCD images of oscillation modes in the PQR laser, respectively;

FIG. 6 is a graph depicting a multi-wavelength oscillating spectrum of a PQR laser and an analysis of wavelength distribution through a calculation;

FIG. 7 is a view schematically depicting a 3D toroidal cavity, using a cylindrical coordinate system;

FIG. 8 is a graph depicting general emission wavelength distributions of GaInN/GaN blue LEDs, GalnN/GaN green LEDs, and AlGalnP/GaAs red LEDs;

FIGS. 9 and 10 are graphs depicting spectra of a PQR laser and a high quality RCLED-type device; and

FIG. 11 is a graph depicting an oscillating spectrum of a red PQR laser according to the present invention.

### BEST MODE FOR CARRYING OUT THE INVENTION

Hereinafter, a photonic quantum ring (PQR) laser a low power consumption display device in accordance with a preferred embodiment of the present invention will be described in detail with reference to the accompanying drawings.

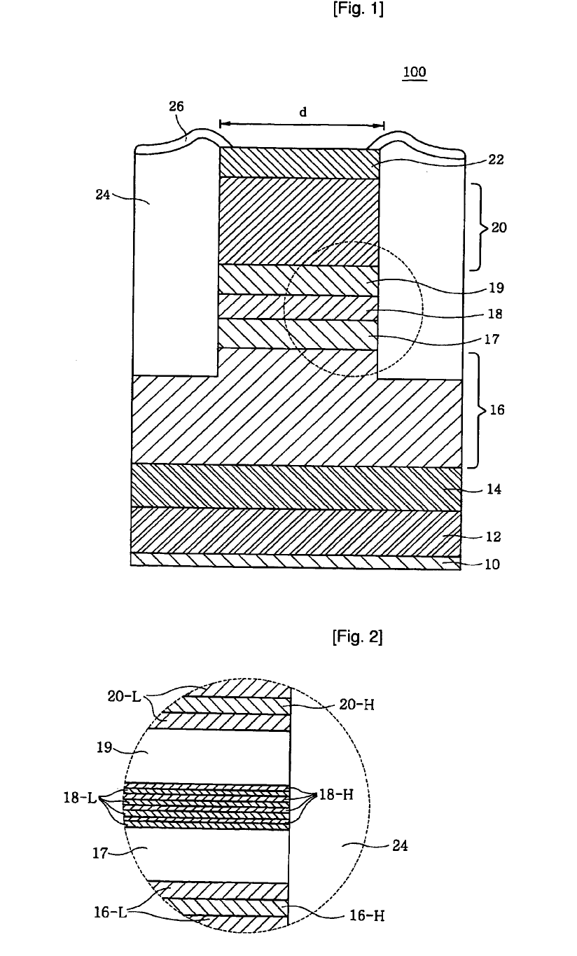

Referring to FIGS. 1 and 2, there are shown cross-sectional and partially-enlarged views illustrating a three dimensional whispering gallery (WG) photonic quantum ring (PQR) laser using a circular vertical-cavity surface-emitting laser (VCSEL) like structure, which is adapted for use in a low power consumption display device in according to the present invention, respectively. The 3D PQR laser shown in FIGS. 1 and 2 is fully disclosed in U.S. Pat. No. 6,519,271 issued on Feb. 11, 2003, the disclosure of which is incorporated herein by reference.

The 3D PQR laser is similar to a vertical cavity surface emitting laser (VCSEL), but exhibits characteristics in which the threshold current, at which the laser begins to oscillate, is in a range of Dto nA considerably lower than those of LED and VCSEL. This 3D PQR laser may be classified as a 3D Rayleigh-Fabry-Perot (RFP) WG mode laser, in property of oscillation spectrums. As shown in FIGS. 1 and 2, the 3D PQR laser is fabricated by employing the steps of epitaxially depositing an active region 18 with a plurality of quantum wells, e.g., four quantum wells, sandwiched between an n-type distributed Bragg reflector (DBR) 16 and a p-type DBR 20 on a substrate 12; forming a cylindrical mesa using a dry etching; surrounding the cylindrical mesa by a polyimide planarization; and padding striped or multiply-segmented p electrodes 26 on top of the cylindrical mesa and one n electrode 10 under the substrate 12. Specifically, the substrate 12 is made of any suitable material, e.g., Gallium Arsenide (GaAs), gallium indium nitride (GaInN), or the like and is typically n+ doped so as to facilitate epitaxial growth of subsequent multiple layers. Typically, any suitable epitaxial deposition method, e.g., molecular beam epitaxy (MBE), metal organic chemical vapor deposition (MOCVD) or the like, is used to make the required multiple layers. These methods allow making an epitaxial deposition of material layers, e.g., aluminum arsenide, gallium arsenide, aluminum gallium arsenide, and the like. It should be understood that epitaxial deposition is used extensively to produce the multitude of layers. After an n+ GaAs buffer layer 14 with a thickness of 0.3D is deposited on the substrate 12, e.g., may be made of n+ GaAs, many layers with two different indices of refraction are stacked one on top of another to form the n-type DBR 16. That is to say that 41 lower layers 16-L of AlₓGa₁₋ₓAs and 40 higher layers 16-H of Al_{y}Ga_{1-y}As are deposited alternately to form the n-type DBR 16 as shown in FIG. 2, wherein 0≦x and y≦1, x and y being preferably 0.9 and 0.3, respectively. AlₓGa₁₋ₓAs has preferably a relative low index of refraction and Al_{y}Ga_{1-y}As has preferably a relative high index of refraction so that the lower layer 16-L with a relative low index of refraction may be adjacent to the active region 18. Each layer of the n-type DBR 16 is a quarter-wavelength λₙ/4 thick, wherein the wavelength λₙ(=λ/n) is a wavelength in its layer of the laser radiation emitted in a VCSEL mode, λ being the free space wavelength of the laser radiation and n being the refractive index for AlₓGa₁₋ₓAs or Al_{y}Ga_{1-y}As. The active region 18 sandwiched between a lower and an upper AlGaAs spacers 17 and 19, each of the lower and the upper AlGaAs spacers 17 and 19 being 850 Å thick, is deposited on the n-type DBR 16, wherein the active region 18 is made of 4 sets of alternating layers of AlₓGa₁₋ₓAs 18-L with a smaller band-gap energy and Al_{y}Ga_{1-y}As 18-H with a larger band-gap energy, z and x being preferably 0.11 and 0.3, respectively so that 4 quantum wells made of AlₓGa₁₋ₓAs 18-L are made in the active region 18 as shown in FIG. 2. Each layer of AlₓGa₁₋ₓAs 18-L and AlₓGa₁₋ₓAs 18-H is preferably 80 Å thick. It should be noted that the total vertical dimension of the two AlGaAs spacers 17 and 19 and the active region 18 is one-wavelength-thickness of the radiation of the VCSEL mode and the vertical dimension of each of the two AlGaAs spacers 17 and 19 and the active region 18 depends on its index of refraction. On the upper spacer 19, many layers with two different indices of refraction are stacked one on top of another so that a p-type DBR 20 with substantially higher reflectivity is formed. That is to say that 30 lower layers 20-L of AlₓGa₁₋ₓAs or Al_{y}Ga_{1-y}As and 30 higher layers 20-H of Al_{y}Ga_{1-y}As are deposited alternately to form the p-type DBR 20 as shown in FIG. 2, wherein x and y are preferably 0.9 and 0.3, respectively. Each layer of the p-type DBR 20 is preferable to be a quarter-wavelength λₙ/4 thick. On the P-type DBR 20, p+ GaAs cap layer 22 is deposited. After the above epitaxial deposition, the sidewalls of the active region 18 and the two spacers 17 and 19 are etched by using a dry etching, e.g., the chemically assisted ion beam etching (CAIBE), so that a smooth cylindrical mesa is formed. It is noted that the surface of the side walls etched by the CAIBE is more uniform than that etched by any other etching method, e.g., the reactive ion etching (RIE). The diameter of the cylindrical mesa can vary from a sub-D to scores of D's

The etched cylindrical mesa is surrounded by a polyimide channel 24 by a polyimide planarization technique. The polyimide channel 24 supports striped or multiply-segmented p electrodes 26 as described below and provides a path to transmit the radiations of the PQR mode generated in the toroidal cavity. The n electrode 10, which may be made of AuGe/Ni/Au, is deposited under the n+ substrate 12 and the striped or multiply-segmented p electrodes 26 are deposited on the p+ GaAs cap layer 22. The metallic n and p electrodes 10 and 26 are ohmic-contacted with the semiconductor, i.e., the GaAs substrate 12 and the p+ GaAs cap layer 22, respectively, by a rapid thermal annealing process.

The PQR laser forms a toroidal cavity type WG mode under a 3D RFP condition in accordance with a vertical confinement of photons by the DBR layers 16 and 20 arranged over and beneath the multi-quantum-well (MQW) active layer and a horizontal confinement of photons by total reflection occurring along lateral boundaries of a PQR laser disk, as in a micro-disk laser. Carriers on the MQW active surface within a ring defined as a toroid are re-distributed in the form of concentric circles of quantum wires (QWRs) in accordance with a photonic quantum corral effect (PQCE), so that electron-hole recombination is generated, thereby producing photons.

The inventors of the present invention found that the power consumption of the PQR laser can be reduced by

$$\frac{FWHM ( LED )}{{\sum }_{m} {FWHM}_{m} ( PQR )}$$

, as compared to the conventional LED, by adjusting the spectral oscillation mode wavelength and inter-mode spacing (IMS) of the PQR laser. That is, the PQR laser of the present invention exhibits a reduction in power consumption corresponding to the ratio of the wide FWHM of the LED to the sum of narrow FWHMs in n-number of modes of the PQR laser. In accordance with the present invention, the adjustments of the oscillation mode wavelength and the inter-mode spacing of the PQR laser are achieved by reducing the radius in a disk of the PQR laser. By achieving a reduction in the radius R of the PQR laser, it is possible to adjust the inter-mode spacing of the PQR laser, at which the PQR laser oscillates discretely at multi-wavelengths within an envelope wavelength range within the gain profile of a given semiconductor material of the PQR laser of several nm to several tens of nm. Further, through such an inter-mode spacing adjustment, it is possible to determine the number of oscillation modes in the entire defined envelope of the PQR laser. As a result, the amount of power consumed in the PQR laser can be controlled. According to the present invention, the radius R of the PQR laser is in a range of 15 D to 2 D depending on the structure and shape (e.g., triangle or rectangular) of the PQR laser and the dedicated semiconductor material, preferably, about 3D. The number of modes, n, in the PQR laser is preferably 1.

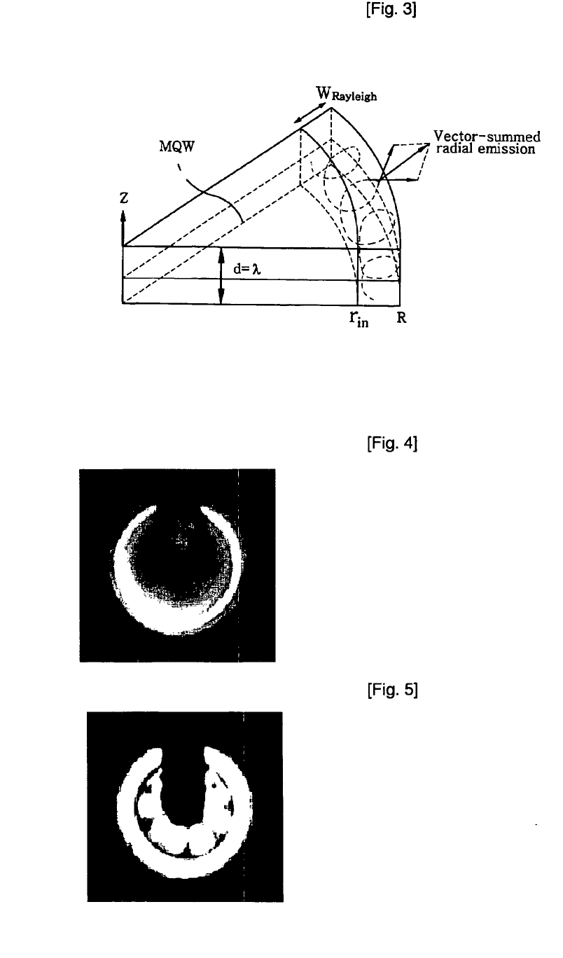

The above described PQR laser, which is a laser light source, has oscillation characteristics and advantages, as follows. First, the current characteristics of the PQR laser will be described. As described above, in the PQR laser, a Rayleigh ring is defined along the circumferential edge of the MQW disk in the 3D toroidal RFP cavity. The PQR laser is driven at an ultra-low state in a threshold current while inducing electron-hole recombination by certain QWR concentric circles in the Rayleigh ring. As a result, the PQR laser even exhibits an emission capability superior over the emission capability of the self-transition type LED at the central portion thereof. Also, the PQR laser has an advantage in that the output wavelength of the PQR laser can be stably maintained by virtue of the QWR characteristics. FIGS. 3, 4 and 5 respectively show 3D toroidal cavity structure of a PQR laser, a PQR mode emitted from a Rayleigh ring in a PQR laser, which is 15 D in diameter, when a current of 12 D is injected, and a VCSEL mode oscillating at a central portion of the PQR laser when a current of 12 mA is injected, respectively.

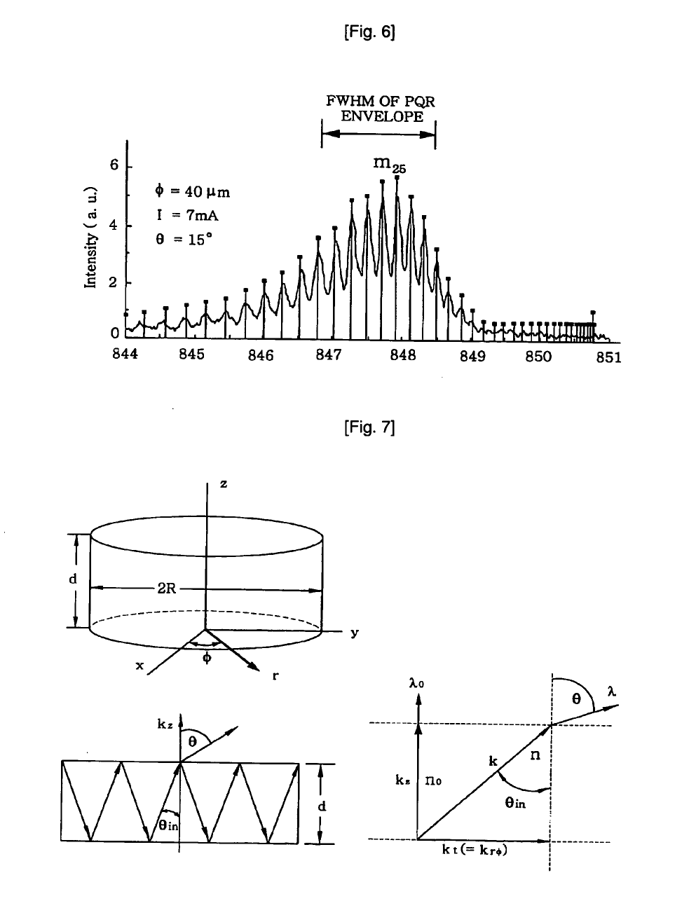

Next, the wavelength characteristics of the PQR laser will be described. The PQR laser has multi-wavelength oscillation characteristics induced from the 3D toroidal cavity structure. FIG. 6 shows a multi-wavelength oscillating spectrum generated when a current of 7 mA is injected into a PQR laser having a diameter of 40D. As known from FIG. 6, it can be noticed that the resonance mode generated in the gain range of the PQR laser discretely forms laser oscillation modes having an average inter-mode spacing (IMS) Δλ of about ˜0.2 nm/mode in the envelope range of the entire spectrum ranging from 845 nm to 850 nm. Accordingly, the PQR laser of the present invention can be applied to low power consumption displays by making oscillation of the above-described wavelength distribution characteristics of the PQR laser in wavelength ranges respectively corresponding to red (R), green (G), and blue (B) of low power consumption devices such as LEDs. In addition, it is possible to generate PQR spectrums having white color by coating yttrium aluminum garnet (YAG) on a blue PQR or using other methods. The number of modes, n, and IMS Δλ in the entire spectrum simply depends on the size of the PQR laser. Such wavelength characteristics can be analyzed by applying the boundary condition between an off-normal Fabry-Perot resonance and a W G resonance to a 3 D toroidal micro cavity. FIG. 7 schematically shows a 3 D toroidal cavity having a radius R and a thickness d, using a cylindrical coordinate system. A general form of light waves, which can be present in a cylindrical cavity, may be expressed by the following Expression 1:

$${Ψ}_{m} ( r , ϕ , z ) ∝ {J}_{m} ( {k}_{t} r ) exp ( \pm im ϕ ) exp ( \pm ⅈ {k}_{z} z ) \qquad [ Expression 1 ]$$

where,

m

is an integer (=0, +1, +2, +3, . . . ),

Jₘ

represents an m-th-order Bessel function, and

k_{z}

and

kₜ(=k_{rφ})

represent longitudinal and transversal components of a wave vector in the cavity. When the boundary condition of the 3D toroidal micro cavity is applied to the Expression 1, it is possible to derive the oscillation modes of the PQR laser. Where an optional traveling wave enters a cavity having a thickness d corresponding to one wavelength, that is,

1−λ

, at an incidence angle of

θᵢₙ

and travels along the cavity while performing repeated transmission and reflection between upper and lower reflection surfaces of the cavity, as shown in FIG. 7, longitudinal and transversal wave vector components of the traveling wave are defined by the following Expressions 2 and 3:
k_{z}=k cos θᵢₙ [Expression 2]
kₜ=k sin θᵢₙ [Expression 3]

where, a wave-number of the cavity,

Jc

, is expressed by

(2π/λ>

,i.e.,

k=(2π/λ)ₙ

, in which

X

is a wavelength in a free space, and

n

is a refractive index at a given wavelength in the cavity.

Where a light wave having an incidence angle of

θᵢₙ

is emitted into the air at an angle of

θ

, a relation of

sin θ=l7 sin θ_{,n}

is established. Further, where it is assumed that

λ₀

represents the wavelength of light emitted into a free space in a longitudinal direction (z-direction), and

n_{O}

represents a refractive index for the wavelength

λ₀

, the longitudinal wave vector component

k_{z}

is expressed by an expression
k_{z}=(2π/λₒ)nₒ
.

By applying these conditions to the Expression 2, and considering the boundary condition,

k_{I}R

, for the WG resonance mode, i.e.,

kₜR=xₘ¹

, where

R

is the radius of the disk, and

xₘ¹

is the first root of the Bessel function

Jₘ(kₜr)

when it is assumed that the Bessel function

Jₘ{kₜr)

corresponds to 0(zero), i.e.,

Jₘ(kr)=O

at a point

r(r=R)

, a quantized emission wavelength (mode) can be derived as expressed by the following Expression 4:

$${λ}_{m} = {λ}_{0} {\frac{{n}_{m}}{{n}_{0}} [ 1 + {( \frac{{x}_{m}^{1} {λ}_{0}}{2 π {Rn}_{0}} )}^{2} ]}^{- 1 / 2} \qquad [ Expression 4 ]$$

From the Expression 4, IMS, that is, \dot{I}^{λ}m+1″^{λ}m\dot{I}
, can be simply derived, as expressed by the following Expression 5:

$$Δ {λ}_{m} \approx \frac{{n}_{0}}{( α {λ}_{0} - {n}_{0} )} \frac{{X}_{0}^{3} {Ax}_{m}^{1}}{{( 2 π {Rn}_{0} )}^{2}} {x}_{m}^{1} \\ where , \\ Δ {x}_{m}^{1} \qquad [ Expression 5 ]$$

is a difference between the first roots of the m-th-order and m+1-th-order Bessel functions, and
α
is a parameter depending on a variation in refractive index in respective modes, but is assumed as a constant. Details are disclosed in Spectrum of three-dimensional photonic quantum-ring microdisk cavities: comparison between theory and experiment, Joongwoo Bae, et al., Opt. Lett. Vol 28(20) pp 1861 1863, October 2003. From the results of the Expression 5, it can be seen that IMS is gradually widened in accordance with an increase in mode order m, and is inversely proportional to the square of the radius
R
of the PQR laser. For example, where the Expressions 4 and 5 are applied to the PQR laser of FIG. 6 in which a current of 7 mA is injected into a PQR laser element having a diameter of 4 OD, it can be seen that the practically measured discrete wavelength distribution of the PQR laser element accurately coincides with the distribution of the calculated multi-wavelength oscillation position. Although IMS increases toward a short wavelength, average IMS is about 0.2 nm/mode. Also, although FWHM varies depending on the respective oscillation wavelengths, it is approximately equal to the average FWHM, that is, FWHM, which is about 0.4 nm (

$${FWHM}_{m} = \sim FWHM = O Λ nm$$

). From the above results, it can be seen that it is possible to adjust the discrete wavelength distribution in an oscillation range covering several nm extremely narrower than the FWHM of LEDs by adjusting the size of the PQR laser, that is, reducing the size of the PQR laser element. This principle means that it is possible to reduce the power consumption by regulating the number of oscillation modes,
n
, while maintaining appropriate color and brightness.

Generally, LEDs, which are commercially available, but are not used for high power application, are driven by about 2V to 4V for injection of a current of 2 OmA to excite gain materials having R, G, and B emission wavelength bands, such as AlGaAs, InGaAsP, GaP, and InGaN. That is, such LEDs consume drive power of 4 OmW to 8 OmW, and have an emission wavelength distribution determined such that FWHM is several nm in a small scale and 100 mm in a large scale in accordance with the details of the manufacture of the LEDs within a wavelength range of about 700 nm to 400 nm according to R, G, or B.

Thus, reducing the radius

R

of the PQR laser can achieve the adjustment of the oscillation mode wavelength and the IMS of the PQR laser. More particularly, in accordance with such a reduction in the radius

R

of the PQR laser, it is possible to increase the IMS, and thus, in accordance with such an IMS's adjustment, it is possible to minimize the number of modes,

n

.

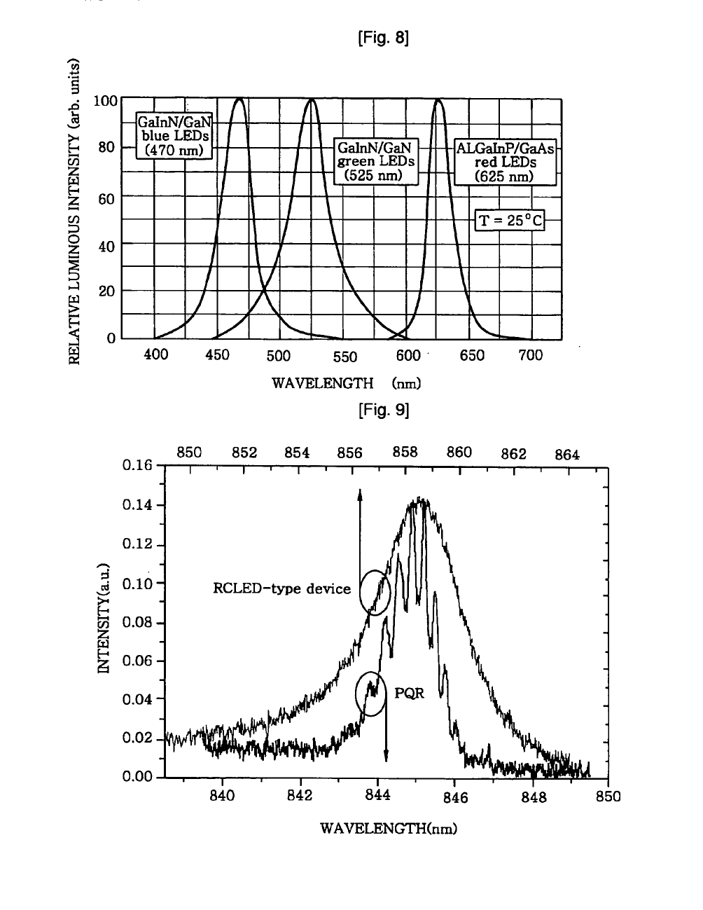

FIG. 8 shows general emission wavelength distributions of GalnN/GaN blue LEDs, GalnN/GaN green LEDs, and AlGalnP/GaAs red LEDs. The LEDs have a total spectrum distribution range of 150 nm, and a FWHM of about ˜25 nm, so that they have a wide wavelength distribution, which may be even up to about 30 times the wavelength distribution of the PQR laser (5 nm×30=150 nm) (After Toyota Gosei Corp., 2000). Where it is assumed that the ratio of the intensity of light emitted from an LED to that of a PQR laser is

$$\frac{7 ( L £ D )}{I ( PQR )}$$

, the ratio of the power consumption of the LED to that of the PQR laser can be derived by the following Expression 6:

$$\begin{matrix}KLED ) \\ KPQR )\end{matrix} \times \begin{matrix}FWHM ( LED ) \\ {\sum }_{M} FWHMJ PQR )\end{matrix} ≅ \begin{matrix}1 ( LED ) \\ KPQR )\end{matrix} \times - \begin{matrix}FWHM ( LED ) \\ nXFWHMJPQR )\end{matrix} - \begin{matrix}KLED ) \\ KPQR )\end{matrix} \times - \begin{matrix}25 nm \\ nXQ 4 nm\end{matrix} \qquad [ Expression 6 ]$$

where,

n

represents the number of oscillation modes in the entire envelope of the PQR laser, and depends on the radius

R

of the PQR laser, as described above. Specifically, the value n is the number of discrete modes included in the FWHM of the envelope of the PQR laser, and is 7 in the case as in FIG. 6. It is preferred that the value

n

be minimal, that is, 1. In this case, the PQR laser is operated in a single mode.

Where it is assumed that

$$\frac{I ( LED )}{I ( PQR )}$$

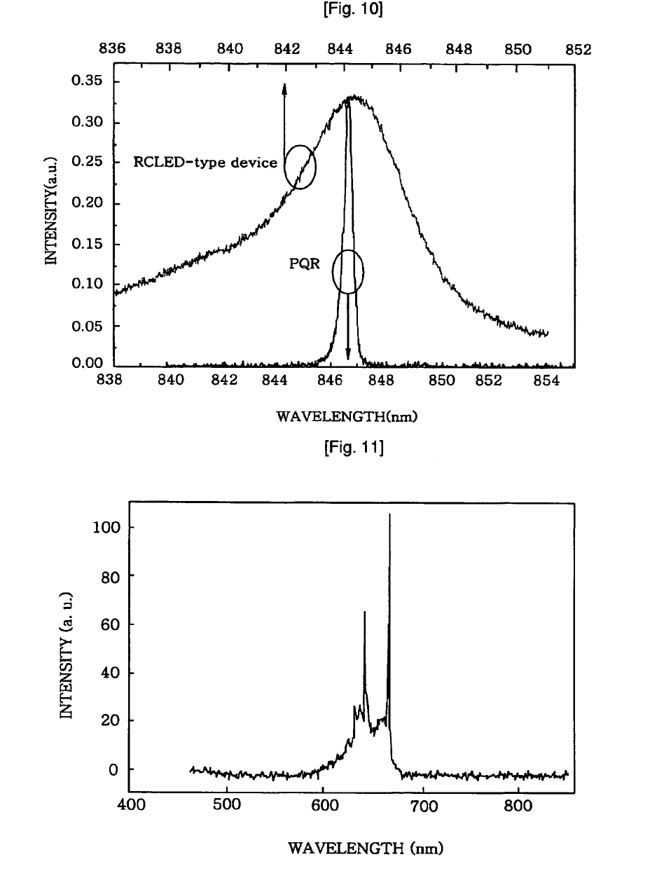

is 1, it is possible to obtain a power gain corresponding to 9 times the power gain of the LED. Such a gain increases gradually as the radius
R
of the PQR laser is reduced. This means that the power required in the PQR laser to emit light of an identical color to that of the LED is reduced. FIGS. 9 and 10, which show embodied examples, are graphs depicting spectra of a PQR laser and a high quality RCLED-type device in a wavelength band of 850 nm. In particular, FIG. 10 shows the spectra of the PQR laser and the high quality RCLED-type device in case where
n=1
. In the case of an RCLED, which uses a resonator to reduce the FWHM thereof by about several nm, it consumes a large amount of power, as compared to the PQR laser. In the case of a single mode PQR laser, it has an increased resistance due to a serial resistance of DBRs depending on the size of the PQR laser. In this case, however, it is possible to sufficiently compensate for the power consumption caused by a higher resistance than that of the LED because the PQR laser oscillates with an extremely low current having a threshold value of several D.

FIG. 11 is a graph depicting an oscillating spectrum generated when a current of 300 D is injected into a red PQR laser having a diameter of 15 D, in which there is shown the entire envelope with a FWHM of 35 nm and two predominant modes oscillating in the envelope range and having a FWHMₘ of 3 nm. As apparent from the above description, the display device of the present invention uses a PQR laser designed to exhibit a threshold current lower than those of LEDs and to have multi-wavelength modes in an envelope wavelength range of several nm to several tens of nm, and consumes reduced power while maintaining desired color and high brightness equal to those of LEDs, through an adjustment of the multi-wavelength oscillation characteristics and the IMS of the PQR laser. Accordingly, the display device of the present invention can be substituted for conventional LEDs having an emission wavelength FWHM of several tens of nm to 100 nm to be used for display devices.

While the present invention has been described with respect to certain preferred embodiments only, other modifications and variations may be made without departing from the spirit and scope of the present invention as set forth in the following claims.

1. A three-dimensional (3D) photonic quantum ring (PQR) laser for a low power consumption display, wherein the PQR laser has a sufficient small radius to adjust an inter-mode spacing (IMS) of oscillation modes discretely multi-wavelength-oscillating in an envelope wavelength range within the gain profile of a given semiconductor material of the PQR laser so that the IMS has a maximal value.
The 3D PQR laser according to claim 1, wherein the adjustment of the IMS to the maximal value causes the number of the oscillation modes oscillating in the envelope to be adjusted to a minimal value.
The 3D PQR laser according to claim 2, wherein the radius of the PQR laser is in a range of 15_{D} to 2_{D} depending on the structure and shape of the PQR laser and the semiconductor material.
The 3D PQR laser according to claim 1, wherein the radius of the PQR laser is about 3_{D.}
The 3D PQR laser according to claim 3, wherein the number of the oscillation modes of the PQR laser is has a value of 1.
The 3D PQR laser according to claim 4, wherein the number of the oscillation modes of the PQR laser has a value of 1.
The 3D PQR laser according to claim 1, wherein the PQR laser oscillates in an oscillation wavelength band corresponding to one of red (R), green (G), and blue (B), to thereby emit corresponding colors therefrom.
The 3D PQR laser according to claim 7, wherein the PQR laser, which oscillate in a wavelength band corresponding blue color, is coated with a material to generate a PQR spectrum having white color.
A three-dimensional (3D) photonic quantum ring (PQR) laser for a low power consumption display, wherein the PQR laser has a sufficient small radius to adjust that the number of oscillation modes discretely multi-wavelength-oscillating in an envelope wavelength range within the gain profile of a given semiconductor material of the PQR laser has a value of 1.
The 3D PQR laser according to claim 9, wherein the radius of the PQR laser is in a range of 15_{D} to 2_{D} depending on the structure and shape of the PQR laser and the semiconductor material.
The 3D PQR laser according to claim 9, wherein the radius of the PQR laser is about 3_{D.}
The 3D PQR laser according to claim 10, wherein the PQR laser oscillates in an oscillation wavelength band corresponding to one of red (R), green (G), and blue (B), to thereby emit corresponding colors therefrom.
The 3D PQR laser according to claim 12, wherein the PQR laser, which oscillates in an oscillation wavelength band corresponding blue (B), is coated with a material to generate a PQR spectrum having white color.
